(19) United States
(12) Patent Application Publication
(10) Pub. No.: US 2005/0176244 A1
(43) Pub. Date: Aug. 11, 2005

(54) Method for manufacturing gate structure of memory

(75) Inventors: Shih-Fan Kuan, Luju Shiang (TW); Kuo-Chien Wu, Miaoli city (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/772,380

(22) Filed: Feb. 6, 2004

(51) Int. Cl. H01L 21/44

(52) U.S. Cl. 438/669

(57) ABSTRACT

A method for manufacturing a gate structure of a memory comprises the steps of providing a substrate; forming a plurality of gates on the surface of said substrate, each gate having a metal layer; forming a photoresist layer of a predetermined pattern on the surface of said substrate and on said gates to selectively form an opening between two of said gates; removing a portion of said metal layer in said gate adjacent to said opening; removing said photoresist layer; and forming an insulating layer on the sidewalls of said gate.

### BACKGROUND OF THE INVENTION

1. Field of the Invention

The present invention relates to a method for manufacturing a semiconductor memory, more specifically, to a method for manufacturing a gate structure of the memory.

2. Description of the Prior Art

Generally, a semiconductor memory manufacturing method uses a contact window to form a contact structure, so as to connect inner parts with an external circuit. FIG. 1a illustrates an exemplary structure of a bit line contact window formed in DRAM semiconductor memory process. Generally, the structure comprises a substrate 11 made of silicon, a gate usually consisting of a poly-silicon layer 12, a WSi layer 13 and a SiN layer, a silicon nitride layer 15 as an insulating layer, a silicon nitride layer 16 as a barrier layer, a BPSG layer 17 as an insulating layer and a TE OS layer 18 as an insulating layer. A contact window 19 is formed in the structure, and is filled with a conducting layer to form a bit line contact structure.

During the formation of the contact window 19, however, due to the long etching time or the like, the shoulder portions of the gate and the silicon nitride layers 15 and 16 are often damaged so that the WSi layer 13, which is used as a metal layer inside the gate, is exposed. Accordingly, the profile of the contact window 19′ is damaged, as shown in FIG. 1b. When the contact window 19′ is filled with the conducting layer, the conductive layer will contact the inner WSi layer 13 of the gate to cause a short circuit.

Therefore, there is a need for a solution to overcome the problems stated above. The present invention satisfies such a need.

### SUMMARY OF THE INVENTION

An objective of the present invention is to provide a method for manufacturing a gate structure of a memory, which can avoid a short circuit occurring between a conducting layer filling the bit line contact window, and the gate.

In accordance with an embodiment of the present invention, the method for manufacturing a gate structure of a memory comprises steps of providing a substrate; forming a plurality of gates on the surface of the substrate, each gate having a metal layer; applying a photoresist layer with a predetermined pattern to cover the substrate surface and the gates to selectively forming an opening between two of the gates; removing a portion of the metal layer of the gate adjacent to the opening; and removing the photoresist layer.

In accordance with another embodiment of the present invention, the method for manufacturing a gate structure of a memory further comprises a step of forming an insulating layer on the sidewall of the gate after removing the photoresist layer.

In accordance with a further embodiment of the present invention, in the method for manufacturing a gate structure of a memory, the amount of the removed portion of the metal layer in the step of removing the portion of the metal layer of the gate is less than 20%.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIGS. 1a and 1b are schematic sectional diagrams illustrating a bit line contact window structure formed by a conventional DRAM semiconductor memory process; and

FIGS. 2a to 2d are schematic sectional diagrams illustrating the respective steps of the method in accordance with the present invention.

### DETIALED DESCRIPTION OF THE PREFERRED EMBODIMENT

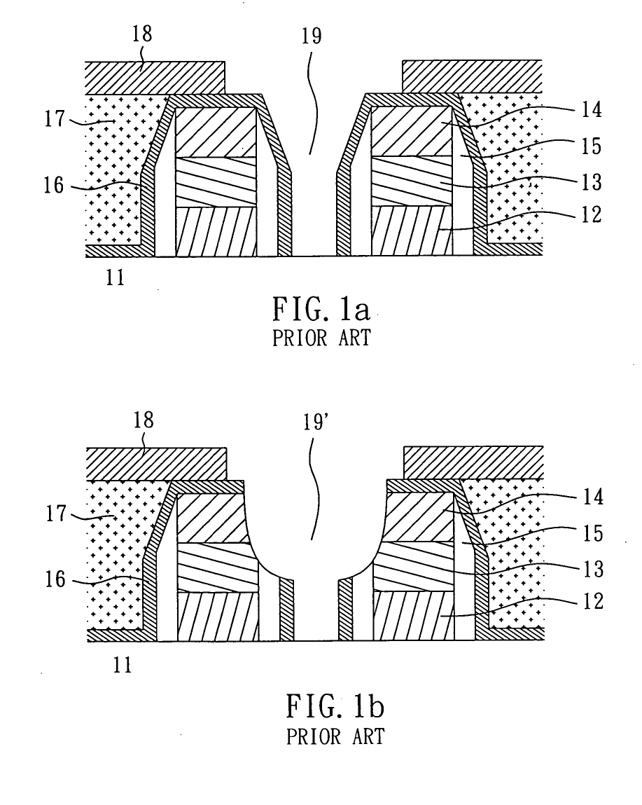

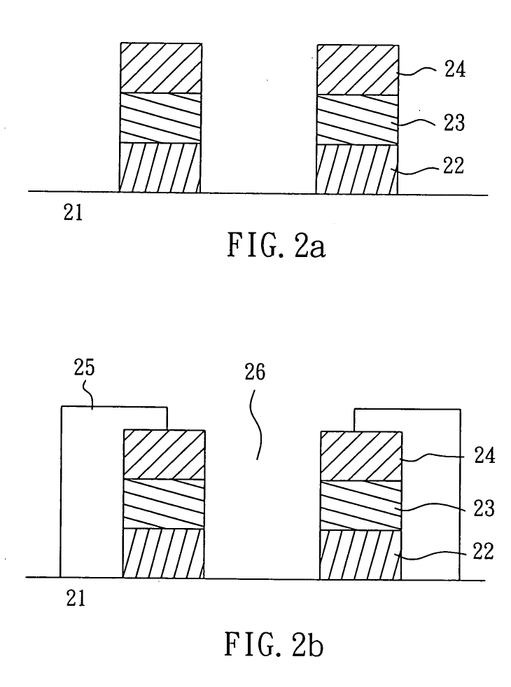

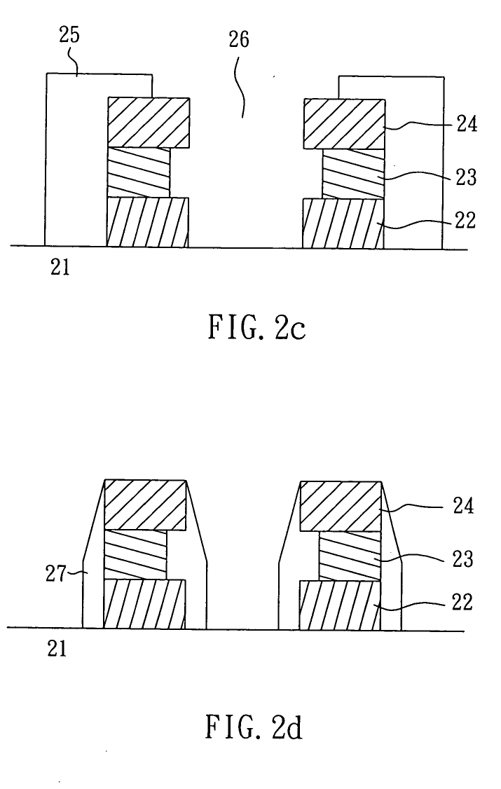

An embodiment of the present invention will be described in detail with reference to the accompanying drawings. FIGS. 2a to 2d are schematic sectional diagrams illustrating the respective steps of the method in accordance with the present invention. The structure shown in FIG. 2a is substantially the same as the substrate and gate shown in FIG. 1a. The structure has a substrate 21, which is generally made of silicon, and a plurality of gates, each of which usually consists of a poly-silicon layer 22, a WSi layer 23 and a SiN layer 24. The WSi layer 23 is used as a metal layer, and the SiN layer is used as a protecting layer for preventing the gate being damged during the subsequent etching process.

In FIG. 2b, a photoresist layer 25 of a predetermined pattern is applied on the surface of the substrate 21 and the gates by deposition and etching, with an opening 26 formed between the two gates to expose the surface of the substrate 21. The location of the opening 26 is the position where a bit line contact window is to be formed.

Then, as shown in FIG. 2c, the portion of WSi layer 23 adjacent to the opening 26 is removed by wet etching, for example. The removed portion is preferably less than 20%, so that the influence to the electrical characteristics of the gate is reduced.

In FIG. 2d, an insulating layer 27, which preferably comprises silicon nitride, is formed on the sidewall of the gate by deposition and etching. The insulating layer 27 is usually referred to a spacer to isolate the gate from other irrelevant circuits.

Further, a bit line contact window structure as that in FIG. 1a, is formed by conventional process.

In the process of forming the bit line contact window, according to the method of the present invention, even a contact window with an incomplete profile as the contact window 19′ in FIG. 1b is formed, the short circuit will not occur between the metal layer (the WSi layer) of the gate and the conducting layer filling the contact window, since the portion of the metal layer adjacent to the contact window opening has been removed. The metal layer of the gate is partially removed off a little portion, so the influence to the electrical characteristics of the gate can be omitted.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method for manufacturing a gate structure of a memory comprises steps of:
providing a substrate;
forming a plurality of gates on the surface of said substrate, each gate having a metal layer;
forming a photoresist layer of a predetermined pattern on the surface of said substrate and on said gates to selectively form an opening between two of said gates;
removing a portion of said metal layer adjacent to said opening; and
removing said photoresist layer.

2. The method as claimed in claim 1, wherein the substrate comprises silicon.

3. The method as claimed in claim 1, wherein the metal layer comprises WSi.

4. The method as claimed in claim 1, wherein the gate further has a poly-silicon formed under the metal layer.

5. The method as claimed in claim 1, wherein the gate further has a protecting layer formed on the metal layer.

6. The method as claimed in claim 5, wherein the protecting layer comprises silicon nitride.

7. The method as claimed in claim 1, wherein the step of removing the portion of the metal layer is performed by wet etching.

8. The method as claimed in claim 1, wherein the step of removing the portion of the metal layer removes a portion less than 20% of the metal layer.

9. The method as claimed in claim 1, further comprising a step of forming an insulating layer on the sidewalls of said gate after removing the photoresist layer.

10. The method as claimed in claim 9, wherein the insulating layer comprises silicon nitride.
